(19) United States
(12) Patent Application Publication
(10) Pub. No.: US 2005/0246113 A1
(43) Pub. Date: Nov. 3, 2005

(54) Equivalent time oscilloscope with compensated response

(76) Inventor: Allen Montijo, Colorado Springs, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/835,759

(22) Filed: Apr. 30, 2004

(51) Int. Cl. G01R 15/00

(52) U.S. Cl. 702/57

(57) ABSTRACT

DSP correction is applied to the equally spaced samples of individual acquisition records to produce individually compensated acquisition records, where the compensation is based upon previous knowledge of what the 'scope is “doing wrong.” This produces dense segments of data that might actually have been sampled, had the hardware not had real-world defects (e.g., frequency dependent attenuation and discontinuities in transmission lines). These segments are merged into an equivalent time collection of correct data, while taking into account the associated shift in the time axis corresponding to the locations of the different segments. The resulting amplitude-corrected time shifted (time, voltage) pairs are an equivalent time representation of a very long pseudo real time acquisition record which is made available to the rendering process.

### BACKGROUND OF THE INVENTION

Digital Sampling Oscilloscopes (DSOs) fall into one of two broad classifications. Both sample the analog values of an input signal and apply them to an ADC (Analog to Digital Converter), whereupon the digitized values are stored in a memory called an acquisition record. “Real time” digital oscilloscopes produce a trace each time they are triggered, and tend to have expensive high performance architectures that are capable of consecutively sampling at high speed a large number of locations along an input waveform. They are prized for their ability to be triggered for a “single shot” that provides a detailed record of a high speed event that does not occur repetitively, and perhaps only infrequently. “Equivalent time” architectures are ones where the repetitive nature of the input waveform is relied upon, and different parts of it are digitized for each of a series of consecutive triggers. The acquisition records are then combined to produce an equivalent acquisition record. In both cases there are often elaborate mechanisms that take the completed acquisition record and process the data therein for presentation in a display, which is commonly a raster scan mechanism driven from a frame buffer. A fair degree of complexity resides in the selecting and massaging of data in the acquisition record to get it to be a displayable image in the frame buffer. The user is allowed to select, after the fact, what time scale (zooming in and out along the X axis) and voltage scale (zooming in and out along the Y axis) the trace is to exhibit. Very often this means extensive interpolation, since there is no particular correspondence between the time and voltage granularity with which the “real data” is stored in the acquisition record and the pixel-to-pixel position spacing in the raster scan display mechanism that is to exhibit the trace. We can't have holes in the trace just because the “real” data fell somewhat on either side of a pixel location. Furthermore, it is common for the trigger event to be located after the start of the acquisition record (negative time), and for the location of the trigger event relative to the start of the displayed portion of the trace to be adjustable (panning).

As digital 'scopes are improved to operate with higher bandwidths, new classes of difficulties emerge, and are met with corresponding solutions. One such difficulty may be classed as “frequency response” and upon investigation, reveals itself to be combination of different causes that tend to have a similar outcome: the measured amplitude of a signal is incorrect, and it is the bandwidth consuming components of signals that account for the errors. For example, there is simple frequency response, where, say, there is some shunt capacitance that is not compensated in view of some series resistance, resulting in an RC filter. Or, perhaps an amplifier is bandwidth limited for whatever reason, and its frequency response rolls off sooner that desired. Another example is reflected power caused by discontinuities in the transmission lines used to couple the system or device under test to the 'scope. While this is a useful phenomenon that is the basis for TDR (Time Domain Reflectometry), and TDR results are often easy to interpret when there is limited bandwidth or only one or two reflections, the ugly truth is that reflected power also re-reflects off ALL the other discontinuities, and the result is often the sum of a Cartesian product of all the ways “the thing can go wrong.” The more bandwidth and the greater the voltage resolution the measurement system has, the worse the results appear to be, even though they were probably always that way, and older equipment just didn't reveal it. When these same results are manifested in a time domain trace of a voltage waveform under measurement, the result often appears to be a fickle and unpredictably uneven frequency response that gives the waveform suspicious properties that are rightly suspected as being spurious artifacts. Another source of frequency dependent errors are various absorptive and dissipative losses in the transmission media. One way to get rid of, or at least reduce these unwanted errors is to substantially eliminate them at their source by “doing everything right.” Not only is this REALLY hard to do, it is also quite expensive, and results in rather delicate instrumentation, since once the operation of a system is no longer explained by lumped constants, but becomes explainable only by distributed ones, the physical attributes of a system become at least as important as the gain cut-off frequencies of the active devices that do the sampling and digitizing, etc. For example, the characteristic impedance of a coaxial cable that connects a high bandwidth active probe to the 'scope might have at one time been the victim of a caster on a swivel chair, yet shows no outward sign of having been squashed. (The culprit who did it massaged it back into shape and then said nothing . . . ) But it retains a 2Ω discontinuity over a half-inch in the middle, and if nothing else is done about it, is as good as ruined for use at 10 GHz.

To cope with this performance situation, high end DSOs of different designs or model numbers have been characterized to discover a particular DSP (Digital Signal Processing) transform, which, for that particular model 'scope ought to flatten out its response. This does not necessarily fix any particular instrument, especially one whose performance is marginal, or is actually broken. But it is a good practical solution for production purposes. A more expensive approach is to individually characterize each instrument produced, and give it its own custom compensatory DSP transform. In either case, the DSP techniques used in the transforms are capable of correcting each of the error mechanisms mentioned above, singly and in combination. However, they impose requirements on the manner in which an acquisition record was produced. The main one, for our purposes, is that all of the samples in the acquisition record to be “fixed” need to have equal spacing along a time axis.

That equal spacing in time requirement is not a particular difficulty for a real time DSO, at least not for a single acquisition record. So long as there is to be just one acquisition record contributing to a trace, each acquisition record is compensated by DSP and the result given to the rendering system for display according to the user's settings.

But let's now consider what happens when the goal is to have a DSO with substantially the performance (save for single shot) of a real time 'scope but that has a REALLY deep memory. Later, we won't restrict the motivating examples to deep memory, but for now it is an easy example to appreciate, so we'll start with it. By “deep memory” we mean an acquisition memory that can hold a very long acquisition record, say many tens of millions of samples. Now, at first impression one might think as follows: “Well, we have this digitizer that will go at 20 GSa/s (Giga Samples per second) for a bandwidth of 10 GHz, and it will produce an acquisition record having a million or so entries. Let's just add more memory and make the acquisition record longer . . . .” This suggestion assumes that the operations of digitizing and storage are independent (compartmentalized) and performed in a serial relation. “You have a fire hose to fill a row of buckets, and to fill more buckets you simply put more buckets in the row and leave the hose on longer . . . .” Unfortunately, this analogy does not describe how the megasample gets made at 20 GSa/s. It is not necessary here to delve deeply into how that operation really is performed; it is sufficient to say that the operation of the ADC mechanism and the memory are quite intertwined, as it were, and offering to supply more memory alone does NOT fix the problem. It is not that it cannot be done in principle, but it is, at present anyway, not an economically practical approach for a product.

Convinced that this is indeed the case, we take a page from equivalent time DSOs. The urge is to take, for a first trigger, a megasample for a first portion of the input waveform, and then for a subsequent trigger another megasample for a second (different) portion of the waveform (by a judicious application of a selected delay after the subsequent trigger), and so on, until we have a collection of acquisition records that, when taken in the proper sequence, describe the measured waveform of interest. At this point all we are giving up is the single shot measurement capability, since we are going to need to trigger several times, and delay each megasamples from their associated trigger event by an appropriate amount of time. By our earlier definition, this mode of operation would be an equivalent time DSO, since not all the samples will have originated on that time axis that will be used to display the trace.

So far, so good. But it is also to be a 10 GHz 'scope, and to obtain superior performance we are compelled to incorporate the DSP compensation strategy that we mentioned above. Now we are faced with the issue of how to preserve the equal spacing between samples that DSP techniques generally require. (As an aside, DSP techniques that do not require regularly spaced samples are known, but they are extremely unattractive.) Within each of the several acquisition records the samples will be equally spaced in time, but the acquisition records as entities have, (despite the judicious after-trigger delays that are indeed known to us) essentially arbitrary amounts of time between when one ends and the next one starts. (If we account for the time used to await a next trigger, and the subsequent delay to position the upcoming acquisition record at the place in the incoming waveform that is where the next segment of samples is to occur, we are left with an arbitrary amount of time less than one sample period.) Thus, we cannot simply merge all the samples into one big acquisition record for compensation by DSP techniques.

Furthermore, there are some other things that also mitigate against attempts at such a merger of individual acquisition records. First of all, there is trigger jitter. Each acquisition record has a trigger associated with it. We are prepared to ignore the trigger-to-trigger delay as though it never happened, and pretend that the second trigger is a magical reach back in time to repeated instance of the first one. That said, we are still obliged to keep track of the difference in time between when the trigger occurs and the next sample, as explained earlier. Even if the input signal were quite stable and exhibited excellent repeatability (i.e., after a trigger the locations of successive events along the waveform of interest are always be the same as they were for a previous trigger), the 'scope is not equipped with the ability to resume a sequence of samples with exactly the same delay after the next trigger as there was for the previous trigger. The timing of the samples is driven by a stable, yet free running, oscillator whose phase cannot be reset at will while it is running. This is a significant effect, since the time base of the 'scope and that of the system under test have no obligation to be related to each other in any way. What is more, the waveform of interest may not have good periodicity, anyway. So the samples might not line up, no matter what we do, when we take some from this instance of the signal and some others from another instance.

Still, the urge to use an equivalent time technique remains strong, as does the need to fix the acquired data with DSP for good oscilloscope performance. What to do?

### SUMMARY OF THE INVENTION

First, we recognize that we can apply DSP techniques to the samples of an individual acquisition record to produce an individual compensated acquisition record, based upon some previous discovery of what the 'scope is “doing wrong.” This DSP compensation is done, individually, for each of the separate acquisition records that are to make up the equivalent time collection of sampled data. Now we have segments of data that we might actually have sampled, had the hardware not had real-world defects (e.g., frequency dependent attenuation and discontinuities in transmission lines). So we do have a collection of correct data, although it is one where each segment has an individual time axis offset associated with it that corresponds to that segment's location along the waveform. Upon consideration, we appreciate that we still have good (time, voltage) pairs to send to the rendering process, and that it is not bothered by the fact that not all the sampled data aligns with its pixel-to-pixel division of the time axis. To deal with such misalignment is a principal excellence of the rendering mechanism. (Some equivalent time DSOs even use random sampling and the rendering mechanism copes with that.) Furthermore, we remember that our data is, if need be or is so specified, very dense (taken at the maximum sample rate all the way through a segment), and that the rendering mechanism's interpolation for pixel value determination is only an issue if the trace is to be at the time scale of highest resolution (and even there we don't exceed the Nyquist limitation), and that even in a genuine real time DSO we can't escape that circumstance. More typically, the displayed time scale is less than the greatest resolution, and the display rendering mechanism copes with this according to various strategies, such as averaging, ignoring data values along intermediate time locations, production of multiple values of Y at certain X locations, etc.

Accordingly, we apply the desired DSP compensation to the equally spaced samples of individual acquisition records to produce individually compensated acquisition records, where the compensation is based upon previous knowledge of what the 'scope is “doing wrong.” This produces dense segments of data that might actually have been sampled, had the hardware not had real-world defects (e.g., frequency dependent attenuation and discontinuities in transmission lines). These segments are merged into an equivalent time collection of correct data, while taking into account the associated shift in the time axis corresponding to the locations of the different segments along the input waveform. The resulting amplitude-corrected time shifted (time, voltage) pairs are an equivalent time representation of a very long pseudo real time acquisition record, which is made available to the rendering process.

### BRIEF DESCRIPTION OF THE DRAWINGS

FIG. 1 is a diagram illustrating one way a waveform can be acquired by a digital oscilloscope operating in accordance with the principles of the invention and incorporating digital signal processing to compensate for frequency related amplitude errors in its response;

FIG. 2 is an expansion of an initial portion of the diagram of FIG. 1, and illustrates additional properties of the oscilloscope's operation;

FIG. 3 is a diagram illustrating the manner in which the principles of FIG. 1 can be used to create a multi-valued waveform, such as an eye diagram; and

FIG. 4 is a simplified flowchart of the operation of an equivalent time digital oscilloscope incorporating digital signal processing to compensate for frequency related amplitude errors in its response.

### DESCRIPTION OF A PREFERRED EMBODIMENT

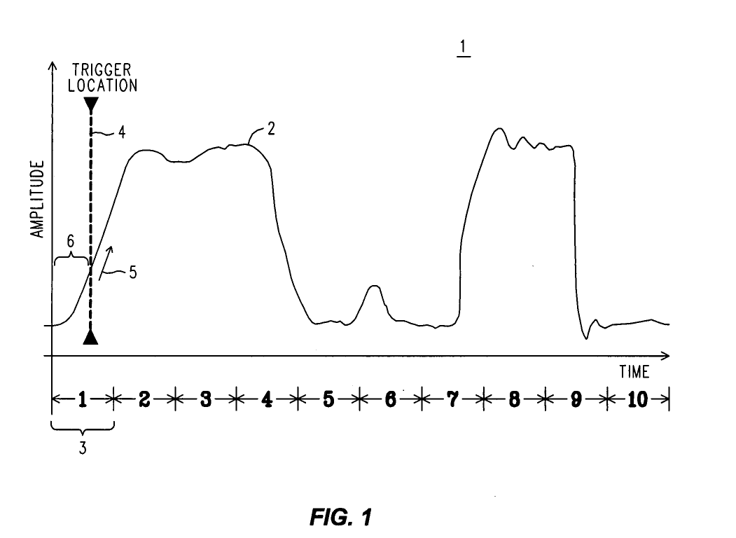

Refer now to FIG. 1, wherein is shown a diagram 1 illustrating the equivalent time acquisition of a waveform 2 that is of a length that is a multiple of what can be acquired as equally spaced samples sequentially stored in one acquisition record by the acquisition hardware. The waveform 2 is shown against a Y amplitude (voltage) axis and an X time axis, as is the usual case. However, note the ten indicated time segments below the time axis, of which the first such time segment 3 is one instance of interest. It will be appreciated that the number of such time segments present will vary depending upon the needs of the individual measurement situation: one reasonable range for the number of such segments is from ten to one hundred, while in principle it is actually from two to however many are needed and can be afforded.

During each of the segments the data acquisition hardware of the 'scope takes some number of consecutive, and equally spaced in time, samples that are digitized and placed into an acquisition record. It is quite possibly—although not necessarily—the case that these samples are taken at a maximum rate and spaced as close together in time as possible. These days it is common for a high end 'scope to have acquisition records of a million or so consecutive samples.

In the figure a trigger event has been detected by a separate (and conventional) hardware implemented trigger circuit (not shown), and a TRIGGER LOCATION 4 is indicated on the diagram as being within the first segment 3. What is shown in this example corresponds to triggering on the rising edge 5 of the input waveform 2, with an amount 6 of “negative time” appearing in the trace to the left of the indicated TRIGGER LOCATION 4. This is arranged by the well-known device of continuing the production of the acquisition record for some selected amount of time after the trigger event: the less selected amount the more negative time shows what transpired before the trigger, up to the size of the acquisition record.

To create an oscillographic trace 2 of this sort, clearly we need to not only acquire the acquisition record for the first segment (3), but also ones for the second, third, and so on, for as many segments as needed. The number of segments is determined by the settings of the oscilloscope's controls; i.e., the time span of the desired equivalent time record is divided by the time span of the acquisition record. Likewise, the operator can specify a sample rate, which might be lower than the maximum rate the 'scope can perform. So, as a related example, the operator might instruct the 'scope to sample at 20 GSa/s with the intent of being able to create a displayable trace representing five hundred microseconds of data. So, (and for simplicity using numbers that are not powers of two and also ignoring any need for overlap,) if there were one million locations per acquisition record, each acquisition record would span fifty microseconds, and ten segments would be needed.

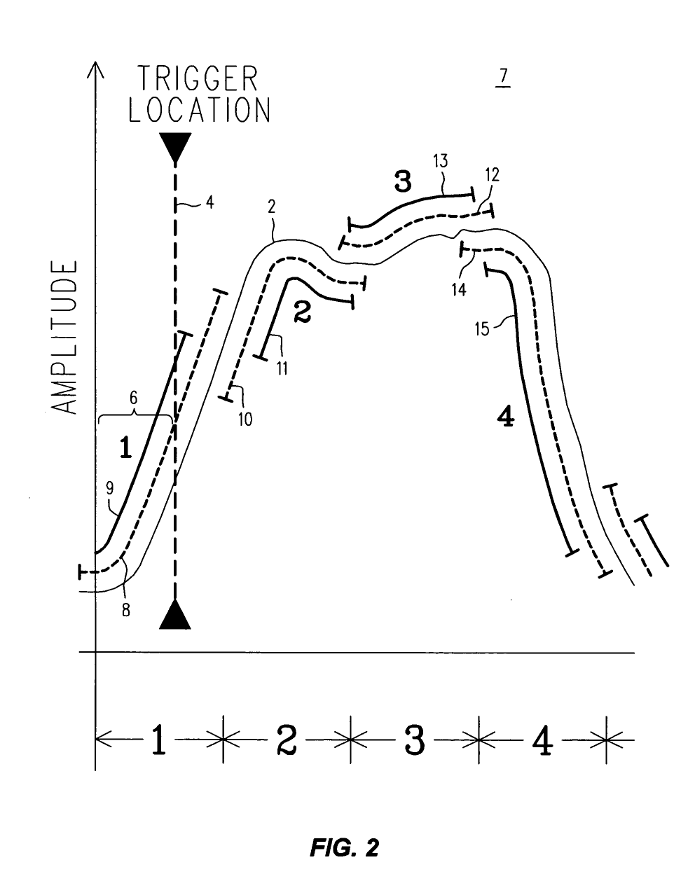

It is not going to be quite that simple, although the idea is valid in principle. First, in a digital architecture with things addressed by binary, octal or hexadecimal quantities, our “million” is probably not 10⁶; it is more likely to be 2²⁰. Next, The DSP processing that will accomplish the compensation is akin to filtering, and it needs to be well started before it gives valid results, so the spans of the various acquisition records need to overlap. The amount of overlap depends upon the DSP mechanism, and might be, for example, on the order of about one hundred samples. This business of overlap will be more clearly visible in FIG. 2, but before considering it, note that our plan is to apply DSP correction to each of the however many acquisition records are produced in connection with a measurement made in accordance with the scheme illustrated in FIG. 1. The corrected results are a collection of compensated acquisition records that are merged into one large equivalent time record that can be given to the rendering process. Since each of these subsequent acquisition records is taken, in the 20 GSa/s example of FIG. 1, at successive locations each another fifty microseconds further along the time axis, with the location of the first being determined by a selected relation to the TRIGGER LOCATION, there will be a supervisory timing mechanism that extracts a second, third, etc., acquisition record starting fifty, one hundred, etc., microseconds after successive instances of the trigger events, as modified by the TRIGGER LOCATION offset in use. We have not shown such a mechanism, as it turns out to be conventional. Prior art equivalent time DSOs let the location of individual samples drift across a repetitive waveform to fill in the samples within an equivalent time record. Even real time DSOs have the ability to locate a solitary acquisition record an arbitrary amount of time after an earlier trigger event. Here, we use that same general mechanism to take not one sample, but to locate an entire sequence of equally spaced samples relative to other such sequences. We stress again that the individual acquisition records are compensated by DSP processing BEFORE they are merged into one collection used by the rendering mechanism to create the displayed trace.

Refer now to FIG. 2, wherein is shown an expansion of the initial portion of the waveform of FIG. 1. What is most of interest to us in this figure is the dashed and solid heavy lines 8-15 that are shown adjacent the first, second, etc., segments identified in FIG. 1. These dashed and solid heavy lines each associated with them the segment numbers shown below the time axis. The dashed heavy lines represent the portion of the input waveform 2 that is actually sampled by the sampling hardware and sent to the DSP processing mechanism. As is well known, if that DSP mechanism is an N tap long FIR (Finite Impulse Response) filter and we are processing K-many samples, then the result is R=K-(N-1) values in length. We want R to be the number of samples available for the rendering of the first segment (3), as well for all the other segments. Hence, the dashed line 8 for the first segment (3) overlaps the dashed line 10 for the second segment, which is in turn overlaps the dashed line 12, which overlaps the dashed line 14, and so on.

We might say that the heavy dashed lines represent the sampled consecutive raw electrical values that are ΔT apart, and that are the input to the DSP process. The solid heavy lines (9, 11, 13 & 15) represent the R-many DSP result values that are also equally spaced (by that same ΔT) among themselves, even though the compensated first sample in, say, the third segment (solid line 13) is not necessarily ΔT after the last compensated sample in the second segment (solid line 11). Recall the discussion in the background about not being able to reset the phase of the free running oscillator that times the taking of the samples. The heavy solid lines do not overlap. As noted before, the rendering mechanism is not bothered by the arbitrary spacing δ between segments (0≦δ≦ΔT), just as long as it gets a valid sequence of (time, voltage) pairs.

In the example shown in FIG. 2 the ten segments are acquired in order, from left to right. This is not a requirement, even though it is often a useful way to proceed. The idea here is that, once it is known how many segments are to be acquired (which is not a mystery—it will be specified by the user or at least determined from other things that the user does specify), an order for those segments can be decided upon. That order might be, as in FIGS. 1 and 2, a strictly adjacent and consecutive one. One the other hand, it might be a random one. Suppose that instead of ten segments there were one hundred. Furthermore, it may take a while for all one hundred triggers to occur. If we let the 'scope display the frame buffer content as it is accumulated during the time required for the one hundred triggers, we will see the trace “emerge” as it is acquired. If the order of the segments is strictly left-to-right, then the trace would start at the left and grow to the right. If we let the order be random (or seemingly so), then the trace will appear to “fill-in all over” as time passes. It could well be the case that whatever we were looking for is ruled out by the time the trace is 20% filled in, allowing us to abort the measurement in favor of some other activity. With a linear sequence for the segments we might have to wait much longer to make such a decision.

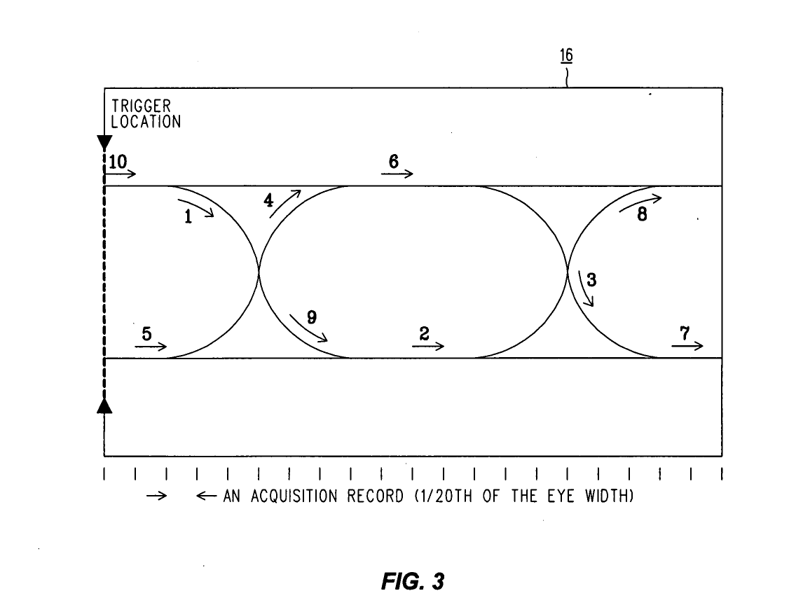

With that in mind, and with an interest in a slightly different application anyway, consider now the eye diagram 16 shown in FIG. 3. We may assume that an external trigger is provided by some clock signal, and that the 'scope has been instructed to randomize the order in which the (in this example, twenty) segments are obtained. After a sufficient number of complete “sweeps,” and relying on known mechanism for displaying multi-valued waveforms, the result is a high definition eye diagram that emerges uniformly.

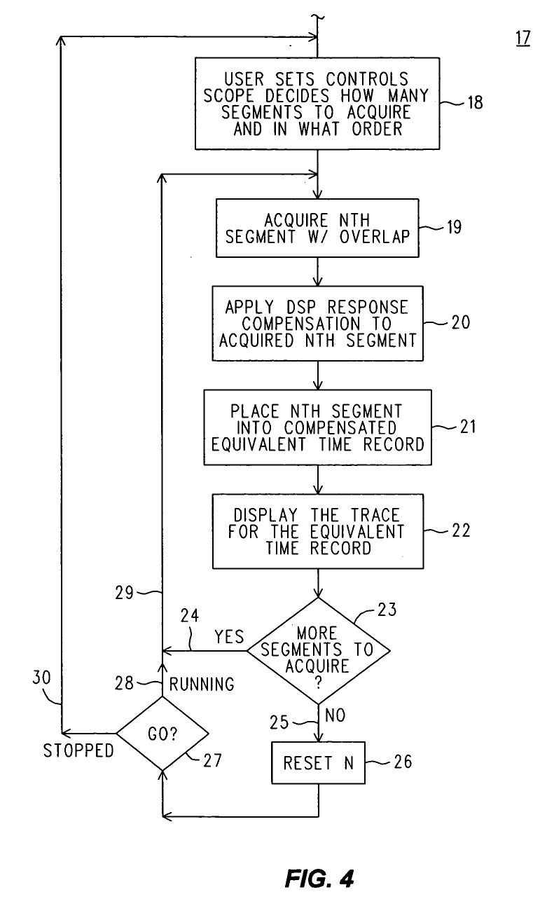

Now refer to FIG. 4, which is a flowchart 17 of the method of creating a compensated equivalent time record from a collection of conventional acquisition records. As the first step 18 in this method, the user sets the control of the 'scope in some desired fashion that produce a situation like that of FIG. 1 or FIG. 3. That is, he wants at his disposal a compensated trace that is longer than it could be if it were limited to the normal acquisition record that the hardware can obtain. From the description of sample rate and trace length the 'scope can decide how many segments, and in what order, to acquire. Not shown in the flowchart, but presumably present, is an instruction to get started (RUN).

Once the 'scope is RUNNING, the next step 19 is to acquire an acquisition record. That is, we get the first, second or next acquisition record, with overlap. The ordinal description of the record determines how long after the next TRIGGER we wait to say that the incoming sample now belongs to that segment. The “overlap” means that we are going to produce longer records from which can be taken the R-many values that will form the collection of DSP-compensated values. Step 19 is followed immediately by step 20, where the acquisition record obtained for step 19 is processed by the DSP mechanism and the R-many result values are produced. At step 21 those R-many result values (which are a compensated, if shorter, acquisition record) are placed into their corresponding location within the waiting equivalent time acquisition record. That equivalent time acquisition record is an input to the rendering process (which is also informed by the user about which part of the overall acquired waveform to show in the display, print to a printer, etc.). Accordingly, step 22 displays the trace. It will be appreciated that other actions besides, or instead of, displaying might be performed. Step 22 amounts to: “The result gets used.” That might, however, be only the “result so far” since all the segments might not yet have been acquired. Thus, a qualifier 23 asks if there are more segments to acquire, and if there are, a path 24 leads to path 29 that returns to steps 19/20, where the next segment in the desired sequence is obtained.

Otherwise, the entire collection of segments has been acquired, and path 25 leads to step 26 that resets whatever internal indices guide the loop of steps 19-23, in anticipation of the loop starting over. That depends on if the 'scope is still RUNNING, or has been STOPPED, as determined by qualifier 27. If RUNNING, path 28 leads to path 29, where the loop of steps 19-23 is repeated. Otherwise, the 'scope has been stopped, and path 30 leads back to step 18, were another measurement activity can be specified and initiated. Presumably, absent instructions to the contrary, the display would continue to show the results of the most recent measurement.

Finally, it will be appreciated that although the examples described above all have acquisition records that are of the same length, it is possible for them to have different lengths. They might all have the same length, or, their lengths might not be equal to one another during the same set of measurements to produce a trace. This variation does not create a problem for the operation of the method that has been described above.

In similar vein, it will also be appreciated that the compensated acquisition records need not form a true partition of the equivalent time record that they create when they are merged. That is, they might well overlap, and in doing so produce X (time) locations that have multiple Y (voltage) values. This does not interfere with the rendering process; for quite some time now it has been capable of coping with such situations. But the DSP compensation process, if applied to the merged original acquisition records would face not only unequal spacing in time, but multiple values. That is a very unhealthy combination for DSP! By doing the DSP compensation BEFORE the merging the multi-valued problem and the unequal spacing problem are avoided (at the time of data capture the spacing in time is uniform and REAL signal has only ONE value at a given instant). Our approach eases the production of eye diagrams, which by their nature are multi-valued.

1. A method of data acquisition for a digital oscillographic instrument operating with a bandwidth, the method comprising the steps of:
(a) sampling at equal time intervals a plurality of work signal values to create an acquisition record representing a continuous fractional segment of the work signal, the plurality of samples meeting the Nyquist requirement for the bandwidth but being in error according to at least one known error mechanism, and the plurality of samples being located relative to a trigger event according to a selected time relationship;
(b) subsequent to step (a), processing the acquisition record of step (a) with DSP techniques to produce a compensated acquisition record corrected for the at least one known error mechanism;
(c) repeating pairs of steps (a) and (b) in sequence; and
(d) subsequent to each instance of step (c), incorporating the associated compensated acquisition record into an equivalent time acquisition record as a segment thereof that corresponds to the continuous fractional segment of the work signal whose signal values were sampled in the associated instance of step (a).

2. A method as in claim 1 further comprising the step of:
(e) displaying a selected segment of the equivalent time acquisition record as an oscillographic trace.

3. A method as in claim 1 wherein the acquisition records of step (a) and the compensated acquisition records of step (b) are consecutive and adjacent continuous fractional segments of the equivalent time acquisition record of step (d).

4. A method as in claim 1 wherein the acquisition records of step (a) and the compensated acquisition records of step (b) are non-adjacent continuous fractional segments of the equivalent time acquisition record of step (d).

5. A method as in claim 1 further comprising the step of:
(e) overlapping the span of the acquisition records of step (a) such that the ending portion of one corresponds to a beginning portion of another.

6. A method as in claim 1 wherein the spans of the acquisition records of step (a) are different from one another.
